(19) United States
(12) Patent Application Publication
(10) Pub. No.: US 2017/0323770 A1
(43) Pub. Date: Nov. 9, 2017

(54) DIELECTRIC WINDOW SUPPORTING STRUCTURE FOR INDUCTIVELY COUPLED PLASMA PROCESSING APPARATUS

(71) Applicant: VNI SOLUTION Co., LTD., Daejeon-si (KR)

(72) Inventor: Saeng Hyun CHO, Suwon-si (KR)

(73) Assignee: VNI SOLUTION Co., LTD., Daejeon-si (KR)

(21) Appl. No.: 15/152,285

(22) Filed: May 11, 2016

(30) Foreign Application Priority Data
May 4, 2016 (KR) 10-2016-0055761

(51) Int. Cl. H01J 37/32

(52) U.S. Cl. CPC H01J 37/32119; H01J 37/3211

(57) ABSTRACT

An Dielectric window of an inductively coupled plasma (ICP) processing apparatus that includes a main container 10 that houses a substrate to be processed S to perform plasma processing, a substrate mounting unit 20 on which the substrate to be processed S is mounted in the main container 10, an exhaust system 30 that discharges gas from inside of the main container 10, a dielectric window 100 that form an upper window of the main container 10, and one or more RF antennas 40 which are installed to correspond to the dielectric windows 100 outside the main container 10 and to which RF power is applied to form induced electric field in the main container 10, wherein the dielectric window 100 is formed as one body from one or more dielectric members, and bonded with a ceramic reinforcing member 120 to at least one surface of the upper surface and the lower surface of the dielectric window 100, including a dielectric window supporting unit 500 supporting at least one of the dielectric window 100 and the ceramic reinforcing member 120 by penetrating at least one of the dielectric window 100 and the ceramic reinforcing member 120 and being connected with a supporting member 12 installed above the main container 10, is provided, so it is possible to minimize power loss by the replacement of a dielectric supporting structure at a region where an antenna is installed, with ceramic.

### CROSS-REFERENCE TO RELATED APPLICATION

This application claims priority to Korean Patent Application No. 10-2016-0055761 filed on May 11, 2016 and all the benefits accruing therefrom under 35 U.S.C. §119, the contents of which are incorporated by reference in their entirety.

### BACKGROUND OF THE INVENTION

### 1. Field of the Invention

The present disclosure relates to an inductively coupled plasma processing apparatus that performs substrate processing, such as substrate etching or deposition.

### 2. Background of the Invention

In order to perform predetermined processing on a substrate in the manufacturing process of a liquid crystal display (LCD) or an organic light-emitting diode (OLED), various plasma processing apparatuses such as a plasma etching apparatus or plasma CVD deposition apparatus are used. A capacitively coupled plasma processing apparatus has been typically used as such a plasma processing apparatus, but in recent, an inductively coupled plasma (ICP) processing apparatus that has a big advantage of being capable of obtaining high-density plasma at high degree of vacuum is receiving attention.

The ICP processing apparatus disposes an RF antenna outside the dielectric window of a main container that houses a substrate to be processed, and applies RF power to the RF antenna simultaneously with supplying a processing gas into the main container to generate ICP in the main container and perform predetermined plasma processing on the substrate to be processed by the ICP. As the RF antenna of the ICP processing apparatus, a planar antenna that has a vortex pattern is being mostly used.

However, with a recent increase in the size of a substrate, there is a need for an increase in the size of a plasma processing apparatus in order to process larger substrate that excesses 1 m in the length of one side thereof.

Thus, as the ICP processing apparatus for processing the large substrate also increases in size, the variation of plasma density on the plane of the substrate to be processed increases and thus there is limitation that it is difficult to perform uniform substrate processing.

In particular, as the ICP processing apparatus also increases in size, the dielectric window is divided into in plural and the divided plurality of dielectric windows are generally supported by the lattice type supporting structure of metallic material.

However, the conventional lattice type supporting structure has a problem in that since the power induced by the antenna is transferred to the metallic supporting structure, Eddy current, arcing, etc. may occur

### SUMMARY OF THE INVENTION

The present disclosure provides a dielectric window supporting structure of inductively coupled plasma (ICP) processing apparatus capable of minimizing the use of the supporting structure of metallic material and minimizing power loss by penetrating at least one of the integrated dielectric window and the ceramic reinforcing member connected at least one surface of the upper surface and the lower surface of the dielectric window.

To achieve these and other advantages and in accordance with the purpose of the present invention, there is provided an dielectric window supporting structure of inductively coupled plasma (ICP) processing apparatus that includes a main container 10 that houses a substrate to be processed S to perform plasma processing, a substrate mounting unit 20 on which the substrate to be processed S is mounted in the main container 10, an exhaust system 30 that discharges gas from inside of the main container 10, a dielectric window 100 that form an upper window of the main container 10, and one or more RF antennas 40 which are installed to correspond to the dielectric windows 100 outside the main container 10 and to which RF power is supplied to form induced electric field in the main container 10, wherein the dielectric window 100 is formed as one body from one or more dielectric members, and bonded with a ceramic reinforcing member 120 to at least one surface of the upper surface and the lower surface of the dielectric window 100, including a dielectric window supporting unit 500 supporting at least one of the dielectric window 100 and the ceramic reinforcing member 120 by penetrating at least one of the dielectric window 100 and the ceramic reinforcing member 120 and being connected with a supporting member 12 installed above the main container 10.

According to one embodiment, the dielectric window supporting unit 500 may include an expansion supporting portion 510 expanding in a horizontal direction for supporting at least one of the dielectric window 100 and the ceramic reinforcing member 120, a supporting rod 520 for supporting at least one of the dielectric window 100 and the ceramic reinforcing member 120, the supporting rod 520 being connected with the expansion supporting portion 510 at one end thereof and with the supporting member 12 at the other end thereof.

The dielectric window 100 may be integrated by bonding a plurality of divided dielectric members 110 with each other.

The plurality of divided dielectric members 110 may be formed with stepped structure at the contacting surface with an adjacent dielectric member 110 so that a part of the dielectric member 110 interposes with each other when viewed in an upper and lower direction.

The divided plurality of the dielectric members 110 may be bonded with each other by ceramic bonding.

The ceramic reinforcing member 120 may be bonded and integrated with a plurality of horizontally divided ceramic reinforcing members.

The plurality of the divided ceramic reinforcing members are formed with stepped structure at the contacting surface with an adjacent ceramic reinforcing member so that a part of the ceramic reinforcing member interposes with each other when viewed in an upper and lower direction.

According to the present invention, the present invention may minimize the use of the supporting structure of metallic material and minimize power loss by penetrating the integrated dielectric window and supporting the dielectric window by the dielectric window supporting unit.

Moreover, the dielectric window supporting unit penetrates a ceramic reinforcing member connected to at least one surface of the upper surface and the lower surface of the dielectric window, and may compensate the weakness of the strength of the dielectric window and more stably support the dielectric window.

In addition, according to the present invention, the dielectric window which antenna is installed over is integrated as one body from the plurality of dielectric members divided with respect to the plane of the dielectric window using ceramic bonding, etc., so the supporting structure of metallic material is unnecessary and power loss due the supporting structure of metallic material can be minimized when forming induced electric field by the antenna.

According to one embodiment, the plurality of divided dielectric members may be bonded to the adjacent dielectric member using stepped structure, protrusion and groove connection structure in the contacting portion, thereby strong bonding between the adjacent dielectric members and then the formation of the integrated dielectric window having lowered structural weakness are possible, and the inside of the main container can be effectively sealed.

### BRIEF DESCRIPTION OF THE DRAWINGS

FIG. 1 is a cross-sectional view showing an inductively coupled plasma processing apparatus according to an embodiment of the present invention.

FIG. 2 is a plan view showing a dielectric window in FIG. 1.

FIG. 3a is a cross-sectional view taken along line III-III and IV-IV in FIG. 2.

FIG. 3b is a cross-sectional view taken along line V-V in FIG. 2.

FIG. 3c and FIG. 3d are cross-sectional views of the respective modified example of FIG. 3a and FIG. 3b.

FIG. 4a and FIG. 4b are plan views showing a dielectric window supporting unit of FIG. 1.

FIG. 5 is a plan view showing an example of an RF antenna that is installed at the apparatus shown in FIG. 1.

FIG. 6 is an equivalent circuit diagram of the RF antenna in FIG. 2.

FIG. 7 is a plan view showing an example of an arrangement of an RF antenna that is installed at the apparatus shown in FIG. 1.

FIG. 8 is a cross-sectional view taken along line VIII-VIII in FIG. 7.

FIGS. 9a to FIG. 9f are cross-sectional views showing modified examples of FIG. 8.

### DETAILED DESCRIPTION OF THE INVENTION

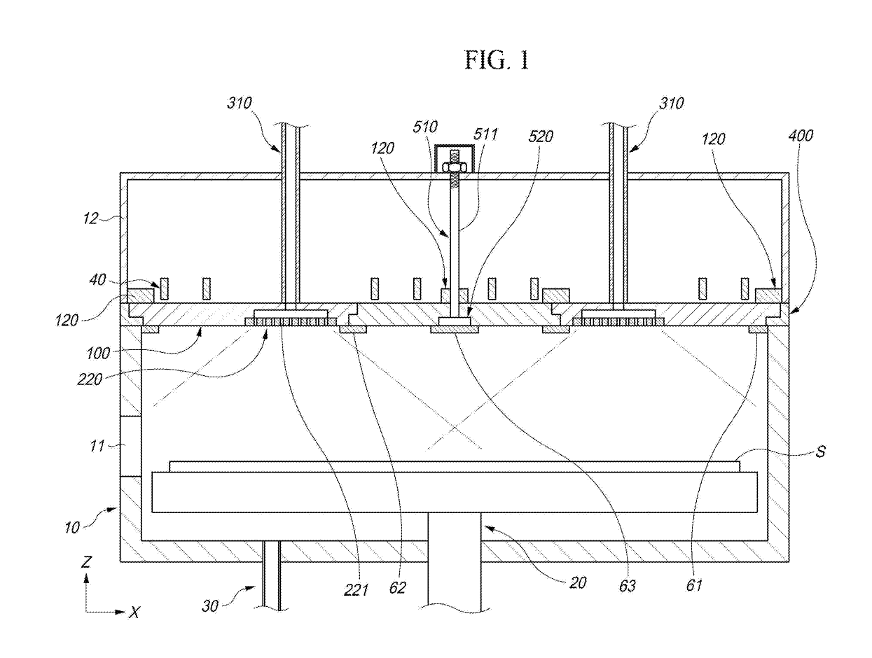

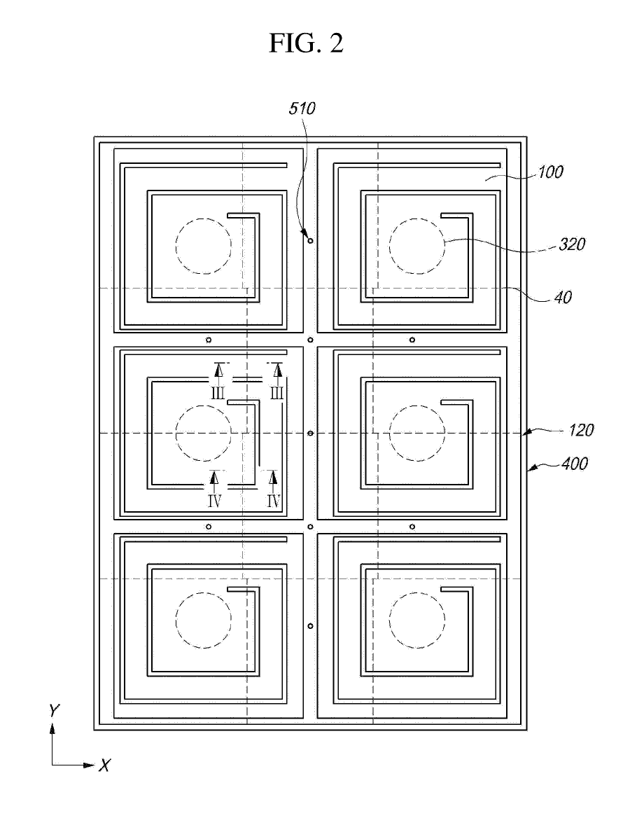

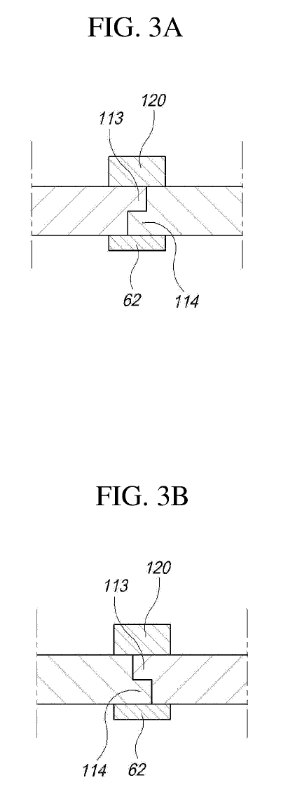

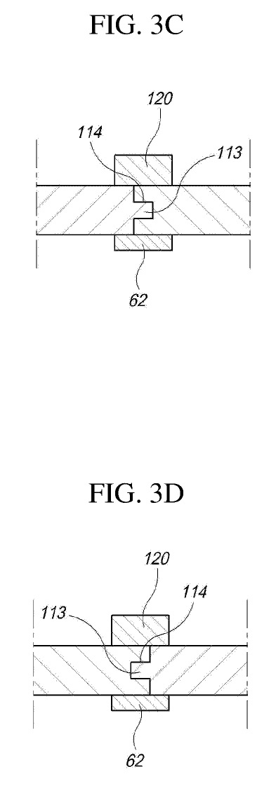

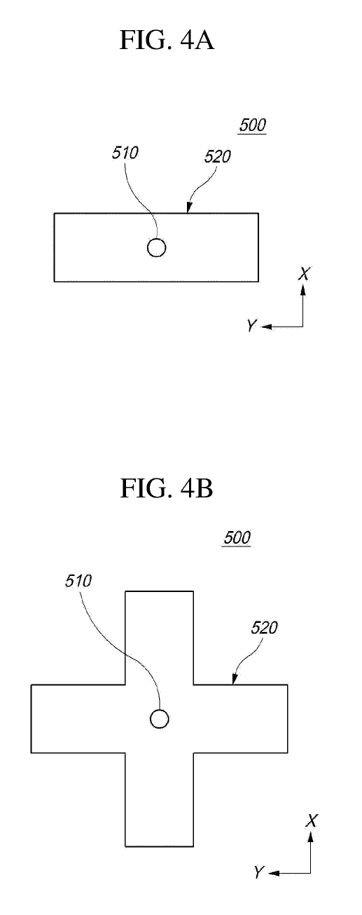

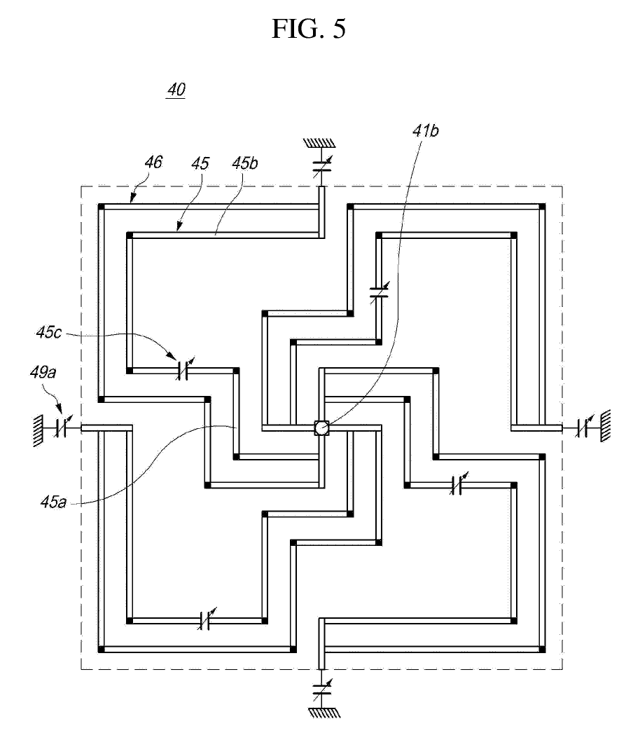

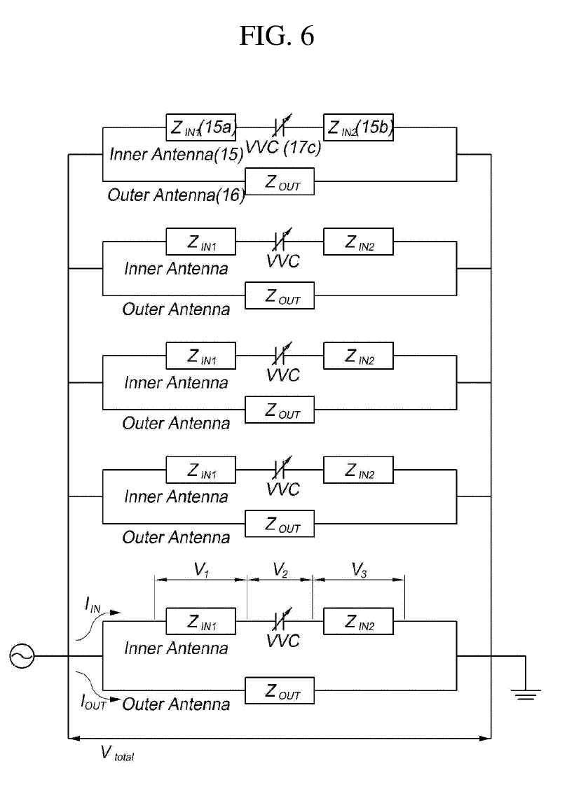

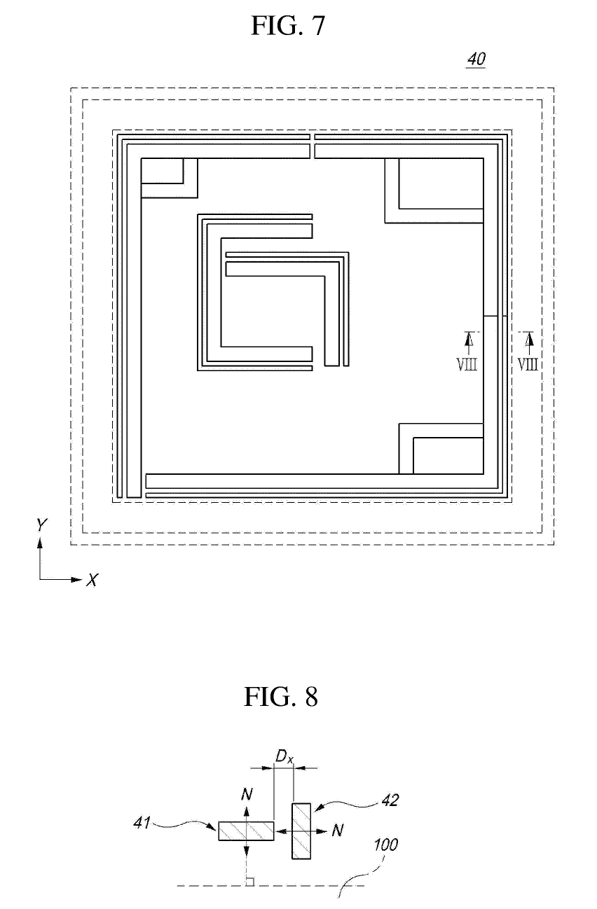

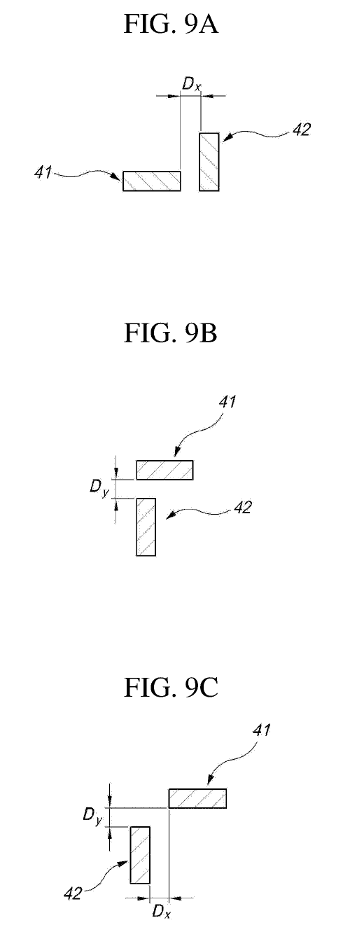

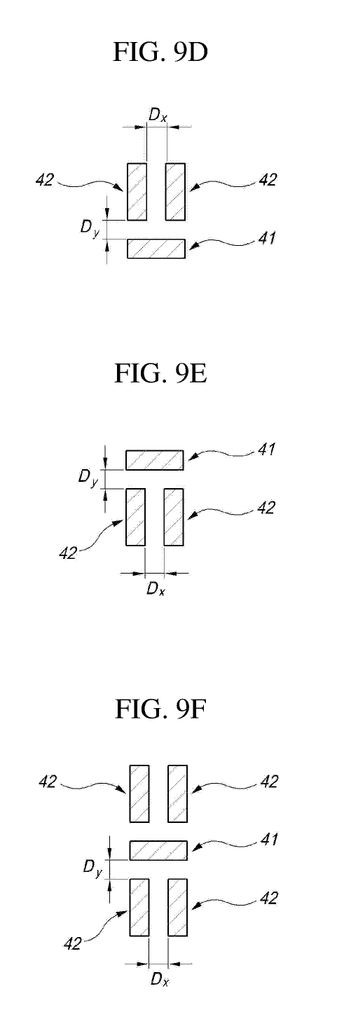

In the following, an embodiment of the present invention is described with reference to the accompanying drawings. FIG. 1 is a cross-sectional view showing an inductively coupled plasma processing apparatus according to an embodiment of the present invention, FIG. 2 is a plan view showing a dielectric wall and a supporting member in FIG. 1, FIG. 3a is a cross-sectional view taken along line III-III and IV-IV in FIG. 2, FIG. 3b is a cross-sectional view taken along line V-V in FIG. 2, FIG. 3c and FIG. 3d are cross-sectional views of the respective modified example of FIG. 3a and FIG. 3b, FIG. 4a and FIG. 4b are plan views showing a dielectric window supporting unit of FIG. 1, FIG. 5 is a plan view showing an example of an RF antenna that is installed at the apparatus shown in FIG. 1, FIG. 6 is an equivalent circuit diagram of the RF antenna in FIG. 2, FIG. 7 is a plan view showing an example of an arrangement of an RF antenna that is installed at the apparatus shown in FIG. 1, FIG. 8 is a cross-sectional view taken along line VIII-VIII in FIG. 7, and FIGS. 9a to FIG. 9f are cross-sectional views showing modified examples of FIG. 8.

The ICP processing apparatus according to an embodiment of the present invention includes a main container 10 that houses a substrate to be processed S to perform plasma processing, a substrate mounting unit 20 on which the substrate to be processed S is mounted in the main container 10, an exhaust system 30 that discharges gas from the inside of the main container 10, a dielectric window 100 that form the upper window of the main container 10, and one or more RF antennas 40 which are installed to correspond to the dielectric windows 100 outside the main container 10 and to which RF power is applied to form induced electric field in the main container 10.

The apparatus may be used in order to perform a substrate processing process, such as etching a metal layer, ITO layer, oxide layer or the like or forming a disposition layer when forming a thin film transistor on the substrate to be processed in manufacturing e.g., a liquid crystal display (LCD) or organic light-emitting diode (OLED).

Here, the substrate S to be processed may generally have a rectangular shape and be 1 m or more in the size of one side.

The main container 10 is a component that houses the substrate to be processed S to form an inner space in which plasma processing is performed.

The main container 10 may have a quadrilateral barrel that is formed from conductive material, e.g., aluminum having anodized inner wall, be assembled and dissembled, and be grounded by a ground line (not shown).

In addition, a gate for introducing/withdrawing the substrate S and a gate valve (not shown) for opening/closing the gate are installed on the sidewall of the main container 10.

A cover member 12 for enclosing the RF antenna 40 described hereinafter may be installed above the main container 10 in order to prevent the electromagnetic field formed by the RF antenna 40 from being leaked to the outside.

The cover member 12 is a component that prevents the electromagnetic field formed by the RF antenna 40 from being leaked to the outside, and various structures for the cover member 12 may be possible.

The substrate mounting unit 20 may be formed from conductive material, e.g., aluminum having an anodized surface. The substrate S mounted on the substrate mounting unit 22 may attached to the substrate mounting unit 22 by an electrostatic chuck (not shown).

In addition, the substrate mounting unit 22 may be connected to a RF power source (not shown) via a matcher (not shown) by a power supply rod (not shown).

The RF power source may apply bias RF power, e.g., RF power having a frequency of 6 MHz to the substrate mounting unit 22 during the plasma processing. By the bias RF power, ions in the plasma generated in the main container 10 may effectively enter the substrate S.

Also, in order to control the temperature of the substrate S, a temperature control device that includes a heating device, such as a ceramic heater or a refrigerant flow path, and a temperature sensor (that are not shown) are installed in the substrate mounting unit 22.

The exhaust system 30 is a component that discharges gas from the inside of the main container 10.

The exhaust system 30 includes an exhaust pipe to which an exhaust device including a vacuum pump is connected, in the bottom of the main container 10, the gas from the main container 10 is exhausted by the exhaust device, and the inside of the main container 10 is set and maintained to be predetermined vacuum atmosphere (e.g., 1.33 Pa) during the plasma processing.

The RF antenna 40 is a component which is installed to correspond to the dielectric window 100 outside the main container 10 and to which RF power is applied to form induced electric field in the main container 10, and may have various structures and patterns as shown in FIGS. 5 to 7.

The RF antenna 40 may be installed within a certain distance from the dielectric window 100 by a spacer (not shown) that is formed from an insulation member.

Also, the RF antenna 40 may be installed in such a manner that a portion thereof is buried in the dielectric window 100, though not shown.

In addition, one or more power supply members (not shown) are installed for power supply to the RF antenna 40, and RF power (not shown) is connected to these power supply members via a matcher (not shown).

During the plasma processing, RF power for induced electric field formation, e.g., RF power having a frequency of 13.56 MHz may be applied from the RF power source to the RF antenna 40. As such, induced electric field is formed in the main container 10 by the RF antenna 40 to which the RF power is applied, and a processing gas is changed to plasma by the induced electric field. The output power of the RF power source is appropriately set to be a value sufficient to generate plasma.

The RF antenna 40 is a component which is installed at a part corresponding to the dielectric window 100 outside the main container 10 and to which RF power is applied to form induced electric field in the main container, and may have various structures and patterns.

According to an embodiment, the RF antenna 40 includes a plurality of distribution line groups that includes a first antenna plate 45 and a second antenna plate 46 that are, on one end, connected to a power supply member 47b, then branch, and are arranged in parallel to each other, and that are merged and grounded on the other end, as shown in FIGS. 5 and 6.

In addition, each distribution line group includes a first antenna plate 45 and a second antenna plate 46 that are, on one end, connected to a power supply member 47b, then branch, and are arranged in parallel to each other, and that are merged and grounded on the other end.

Here, the first antenna plate 45 and the second antenna plate 46 may have a plate shape that has their arrangement directions as length directions.

The RF antenna that has such a structure may be arranged in various forms as shown in FIG. 5.

According to an embodiment, the RF antenna 40 may be arranged in a spiral shape outwards from the central portion of the dielectric window 100.

The first antenna plate 45 may include an inner antenna plate 45a that is connected to the power supply member 47b on one end, an outer antenna plate 45b that is grounded on the other end, and a variable capacitor 45c that is installed between the inner antenna plate 45a and the outer antenna plate 45b.

When as such, the first antenna plate 45 includes the variable capacitor 45c between the inner antenna plate 45a and the outer antenna plate 45b, it is possible to uniformly form plasma formed by the RF antenna 40 through the adjustment of the variable capacitor 45c.

The variable capacitor 45c is a component that is installed between the inner antenna plate 45a and the outer antenna plate 45b to change a capacitor value to optimally form uniform plasma.

In addition, a vacuum variable condenser may be used as the variable capacitor 45c.

The RF antenna 40 that includes the plurality of distribution line groups is installed in various structures; for example, three or four RF antennas may be arranged to correspond to the plane shape of the dielectric window 100, such as a rectangle or circle.

According to an embodiment, the dielectric window 100 may have a plan view corresponding to a rectangle and four distribution line groups may be installed so that the distribution line groups may be grounded at the center of each side of the rectangle.

Here, the power supply member 47b branches from the center of the dielectric window 100 toward the center of each side to be four branches and then is connected to the four distribution line groups, respectively.

In addition, the first antenna plate 45 and the second antenna plate 46 may include a first bent portion that forms 90° with respect to the power supply member 47b, a second bent portion that forms 90° with respect to the first bent portion, a third bent portion that forms 270° with respect to the second bent portion, a fourth bent portion that forms 270° with respect to the third bent portion, and a fifth bent portion that forms 90° with respect to the fourth bent portion.

The first bent portion and the second bent portion are generally positioned at the central portion of the dielectric window 100, the fourth bent portion and the fifth bent portion are generally positioned at the edge portion of the dielectric window 100, and the third bent portion connects the central portion to the edge portion.

In such a plasma optimization, each of the plurality of distribution line groups may be additionally connected to the variable capacitor 19a, such as a vacuum variable condenser and then grounded.

In such a plasma optimization, each of the plurality of distribution line groups may also be connected to the power supply member 17b after being additionally connected to the variable capacitor (not shown), such as a vacuum variable condenser.

In such a plasma optimization, each of the plurality of distribution line groups may also control the current of the second antenna plate 16 together when adjusting the capacitor of the first antenna plate 15.

The above-described structure may be used for voltage control through the first antenna plate 45 in which the variable capacitor 45c is installed, and it is possible to combine current control by the second antenna plate 46 that has no variable capacitor 45c, thus more efficient plasma control is possible.

The plasma formed in the main container 10 depends on the structure and pattern of the RF antenna 40 that is installed over the dielectric window 100.

In particular, the RF antenna 40 may be installed in the pattern and structure shown in FIGS. 5 and 7.

According to a more particular embodiment, as shown FIGS. 7 to 9f, the RF antenna 40 has a plate structure having width and thickness, and may be a combination of a horizontal antenna portion 41 and a vertical antenna portion 42. The normal N of a surface of the RF antenna having the width in the horizontal antenna portion 41 is perpendicular to the top surface of the dielectric window 100 and the normal N of a surface of the RF antenna having the width in the vertical antenna portion 42 is parallel to the top surface of the dielectric window 100.

The horizontal antenna portion 41 is a portion in which the normal N of a surface of the horizontal antenna portion 41 in the RF antenna 40 having the width is perpendicular to the top surface of the dielectric window 100, and may be arranged to be parallel to the top surface of the dielectric window 100.

In addition, the horizontal antenna portion 41 may have various structures; for example, it may be an independent member or coupled integrally to another part.

The vertical antenna portion 42 is a portion in which the normal N of a surface of the vertical antenna portion 42 in the RF antenna 40 having the width is parallel to the top surface of the dielectric window 100, and may be arranged to be perpendicular to the top surface of the dielectric window 100.

In addition, the vertical antenna portion 42 may have various structures; for example, it may be an independent member or coupled integrally to another part.

The present invention may have an optimal arrangement and structure through an experiment as a combination for controlling plasma density formed by a combination of the horizontal antenna portion 41 and the vertical antenna portion 42, i.e., in a series, parallel or series-parallel combination.

According to an embodiment, the combination of the horizontal antenna portion 41 and the vertical antenna portion 42 may be installed over a whole of an upper window or locally, e.g., at an edge portion that is the weak portion of plasma uniformness or at the center of the edge.

In addition, a pattern of the combination of the horizontal antenna portion 41 and the vertical antenna portion 42 may have various embodiments as shown in FIGS. 8 to 9c.

According to an embodiment, the horizontal antenna portion 41 and the vertical antenna portion 42 may be disposed at a distance Dx in the horizontal direction as shown in FIGS. 9a and 9c.

Here, regarding the relative height between the horizontal antenna portion 41 and the vertical antenna portion 42, the horizontal antenna portion 41 may be disposed near the center of the vertical antenna portion 42 as shown in FIG. 8, and the horizontal antenna portion 41 may be disposed around a center near the upper or lower end of the vertical antenna portion 42 as shown in FIGS. 9a and 9c.

Also, regarding a pattern of the combination of the horizontal antenna portion 41 and the vertical antenna portion 42 may be disposed at a distance Dx in the horizontal direction as shown in FIGS. 8, 9a and 9c.

According to another embodiment, one or more vertical antenna portions 42 may be installed at at least one of the upper and lower sides of the horizontal antenna portion 41 as shown in FIGS. 9b, and 9d to 9f.

According to another embodiment, the vertical antenna portions 42 may be installed at at least one of the upper and lower sides of the horizontal antenna portion 41 as shown in FIG. 9b.

According to another embodiment, a pair of the vertical antenna portions 42 may be installed at the upper side of the horizontal antenna portion 41 as shown in FIG. 9d.

According to another embodiment, a pair of the vertical antenna portions 42 may be installed at the lower side of the horizontal antenna portion 41 as shown in FIG. 9e.

According to another embodiment, the vertical antenna portion 42 may be installed in pairs at the upper and lower sides of the horizontal antenna portion 41 as shown in FIG. 9f.

FIGS. 9d to 9f and embodiments thereof may also be performed as embodiments of the states vertically rotated from states in the drawings.

That is, the horizontal antenna portion 41 and the vertical antenna portion 42 may also be disposed in such a manner that the top surface of the dielectric window 100 is vertically disposed based on FIGS. 9d to 9f.

In other words, the horizontal antenna portion 41 and the vertical antenna portion 42 may be exchanged in FIGS. 9d to 9f.

Since induced electric field change and control at the lower part thereof are possible by various patterns as described above, it is possible to appropriately control formed plasma density.

The dielectric window 100 is a component that forms the upper window of the main container 10 and forms induced electric field below the dielectric window 100 by the RF power application of the RF antenna 40 that is installed over the dielectric window 100.

The dielectric window 100 may be installed in one or more, and may be formed from ceramic such as Al₂O₃, quartz or the like.

According to an embodiment, the dielectric window 100 has a feature in that the dielectric window 100 is integrated from a plurality of dielectric members 110 divided in a horizontal direction.

The dielectric member 110 is a component which forms an integrated dielectric window 100 by being bonded with the adjacent dielectric member 110, and various planar shape of the dielectric member 110 such as circular plate, polygonal plate, etc. according to the dividing structure may be possible.

According to the detailed embodiment, the desirable planar shape of the dielectric window 100 is a rectangle, and the rectangular dielectric members 110 may be divided in plural in one side direction in the pair of sides of the rectangular dielectric window 100 as shown in FIG. 2.

According to the more detailed embodiment, the rectangular dielectric members 110 may be connected with each other in the lattice structure in planar direction, and it is desirable that the boundary line L₁ between the two dielectric members 110 may miss the adjacent boundary line L₂ between the two adjacent dielectric members 110 on the way.

In FIG. 2, the dotted region shows an example that the divided pattern in the horizontal direction and the vertical direction for the dielectric window 100, each boundary line in the vertical direction misses each other on the way.

And as shown in FIGS. 2, 3a to 3d, the plurality of divided dielectric members 110 may be bonded to each other by the stepped structure or protrusion 113 and groove 114 structure at the contacting surface with the adjacent dielectric member 110 so that a part of the dielectric member 110 interposes with each other when viewed in an upper and lower direction.

Here, the stepped structure in the boundary line L₁ between the two dielectric members 110 may also be formed in the other direction, i.e. in symmetry with the other stepped structure in the boundary line L₂ between the two adjacent dielectric members 110 as shown in FIGS. 2, 3a to 3d.

And the plurality of divided dielectric members 110 may be bonded by the various bonding methods such as epoxy bonding, high-temperature epoxy bonding, ceramic bonding, and brazing (ceramic melting bonding) in order to minimize the influence of the induced electric field, and desirably bonded by epoxy bonding, high-temperature epoxy bonding, ceramic bonding, and brazing (ceramic melting bonding), especially, the ceramic bonding for the uniformity of the formation of the induced electric field.

Also the dielectric window 100 may be bonded to at least one surface of the upper surface and the lower surface of the dielectric window 100 by a ceramic reinforcing member 120 of ceramic material.

And the ceramic reinforcing member 120 may be bonded to at least one surface of the upper surface and the lower surface of the dielectric window 100 by ceramic bonding.

The ceramic reinforcing member 120 may have ceramic material such as Al₂O₃, and is a component for enhancing structural strength by being bonded to at least one surface of the upper surface and the lower surface of the dielectric window 100.

According to the detailed embodiment, when the dielectric window 100 has a rectangle planar shape, the dielectric window 100 may be bonded with a ceramic reinforcing member 120 of lattice structure to at least one surface of the upper surface and the lower surface of the rectangle dielectric window 100.

In addition, the ceramic reinforcing member 120 may be divided into a plurality of ceramic reinforcing members similarly with the dividing structure of the dielectric window 100, and the plurality of ceramic reinforcing members may be bonded with each other by epoxy bonding, high-temperature epoxy bonding, ceramic bonding, brazing (ceramic melting bonding), etc.

*96 And as shown in FIGS. 3a to 3d, the plurality of the divided ceramic reinforcing members may be formed with stepped structure or the structure of protrusion and groove at the contacting surface with an adjacent ceramic reinforcing member so that a part of the ceramic reinforcing member interposes with each other when viewed in an upper and lower direction.

Here, the plurality of the divided ceramic reinforcing members may be bonded by various bonding methods such as epoxy bonding, high-temperature epoxy bonding, ceramic bonding, and brazing (ceramic melting bonding), and desirably bonded by epoxy bonding, high-temperature epoxy bonding, ceramic bonding, and brazing (ceramic melting bonding), especially, the ceramic bonding for the uniformity of the formation of the induced electric field.

A gas injecting structure is installed at at least a portion of the dielectric window 100 to be capable of performing the injecting control of processing gas on the substrate to be processed to be capable of performing uniform substrate processing.

That is, the structure of the ICP processing apparatus according to an embodiment of the present invention is characterized in that a diffusion plate 220 that diffuses processing gas into the main container 10 is provided with, and the diffusion plate 220 is formed at at least a portion of the bottom surface of the dielectric window 100.

The diffusion plate 220 is a component that diffuses the diffused processing gas into the main container 10.

According to an embodiment, the diffusion plate 220 may have the same material as the dielectric window 100, and may be formed integrally with the dielectric window 100 or as an independent member.

In addition, in the case where the diffusion plate 220 is formed separately from the dielectric window 100, there may be various coupling techniques, such as bolting, epoxy bonding, high-temperature epoxy bonding, ceramic bonding, or brazing (ceramic melting bonding), and for the uniformness of induced electric field formation, the epoxy bonding, the high-temperature epoxy bonding, the ceramic bonding, or the brazing (ceramic melting bonding), especially the ceramic bonding is desirable.

In addition, the diffusion plate 220 comprises a plurality of injection holes 221 so that processing gas may be diffused into the main container 10.

The diffusion plate 220 may have various embodiments according to an installation structure at the dielectric window 100.

The diffusion plate 220 may include a diffusion space that is connected to the branch pipe 310 of a processing gas supply pipe 300 to previously diffuse a processing gas.

For the formation of such a diffusion space, a separate additional diffusion plate may be additionally installed or as shown in FIG. 1, a diffusing unit formed integrally with the dielectric window may be formed.

The diffusing unit is a component that is formed separately form or integrally with the dielectric window 100 to diffuse the processing gas supplied through the branch pipe 310 to the diffusion space through a diffusion hole, and may have various configurations.

As the embodiment, although the case that the gas injecting structure is installed at the dielectric window 100 is only exemplified, various examples such that the gas injecting structure may be connected to the inner wall of the main container 10, or separately connected with the dielectric window 100 other than the dielectric window 100 may be possible.

Meanwhile, the dielectric window 100 may be supported by the dielectric supporting unit 400 connected with the upper end of the main container 10.

The dielectric supporting unit 400 is a component that is coupled to the upper end of the main container 10 and supports the dielectric window 100 to seal the inside of the main container 10.

According to an embodiment, the dielectric supporting unit 400 may have the L-shaped structure in cross section in order to support the dielectric window 100 directly or indirectly.

In addition, the dielectric supporting unit 400 may have metallic material such as aluminum or an alloy thereof.

For the sealing of the inside of the main container 10, O-rings 51 may be desirably installed on a surface at which the dielectric supporting unit 400 and the dielectric window 100 are in contact with one another.

Shield members 61, 62 may be installed at the lower surface of the dielectric supporting unit 400 and the lower surface of the dielectric window 100, the boundary region contacted each other by the lower surface of the bonded dielectric members 110 in order to prevent the damage due to the permeation of plasma ions, radicals, etc.

The Shield members 61, 62 are a component for preventing the damage due to the permeation of plasma ions, radicals, etc. in the boundary region where at the lower surface of the dielectric supporting unit 400 and the lower surface of the dielectric window 100 contact each other, and the boundary region contacted each other by the lower surface of the bonded dielectric members 110, and are installed at the boundary region where at the lower surface of the dielectric supporting unit 400 and the lower surface of the dielectric window 100 contact each other, and the boundary region contacted each other by the lower surface of the bonded dielectric members 110

According to the detailed embodiment, they may be installed by crossing and closely contact the boundary region where at the lower surface of the dielectric supporting unit 400 and the lower surface of the dielectric window 100 contact each other, and the boundary region contacted each other by the lower surface of the bonded dielectric members 110.

Meanwhile, since pressure is applied to the dielectric window 100 and the ceramic reinforcing member 120 due the formation of processing pressure, the processing pressure much lower than the atmospheric pressure in the inside of the main container, it needs to be structurally reinforced.

Therefore, the present invention desirably includes a dielectric window supporting unit 500 supporting at least one of the dielectric window 100 and the ceramic reinforcing member 120 by penetrating at least one of the dielectric window 100 and the ceramic reinforcing member 120 and being connected with a supporting member 12 installed above the main container 10.

Here, the supporting member 12 is a component for supporting at least one of the dielectric window 100 and the ceramic reinforcing member 120 by the dielectric window supporting unit 500 that installed above the main container 10.

According to one embodiment, the supporting member 12 may be the cover member installed above the main container 10 in order to prevent the electromagnetic field formed by the RF antenna 40 from being leaked to the outside.

According to another embodiment, the supporting member 12 may be a frame member for supporting at least one of the dielectric window 100 and the ceramic reinforcing member 120 in the above of the main container 10.

The dielectric window supporting unit 500 is a component that supports at least one of the dielectric window 100 and the ceramic reinforcing member 120 by penetrating at least one of the dielectric window 100 and the ceramic reinforcing member 120 and being connected with a supporting member 12 installed above the main container 10.

*122 According to one embodiment, the dielectric window supporting unit 500 may include an expansion supporting portion 510 expanding in a horizontal direction for supporting at least one of the dielectric window 100 and the ceramic reinforcing member 120, a supporting rod 520 for supporting at least one of the dielectric window 100 and the ceramic reinforcing member 120, the supporting rod 520 being connected with the expansion supporting portion 510 at one end thereof and with the supporting member 12 at the other end thereof.

The expansion supporting portion 510 is a component that expands in a horizontal direction for supporting at least one of the dielectric window 100 and the ceramic reinforcing member 120.

The expansion supporting portion 510 may have various shapes such as “−” shape, “+” shape, polygonal shape, circular plate shape, etc. and structures as shown in FIGS. 4a and 4b.

The supporting rod 520 is a component that supports at least one of the dielectric window 100 and the ceramic reinforcing member 120, and is connected with the expansion supporting portion 510 at one end thereof and with the supporting member 12 at the other end thereof, and various structures for the supporting rod 520 may be possible.

Here, the other end of the supporting rod 520 may be connected with the supporting member 12 by various connections, and may be formed with a screw portion for being connecting with a nut 530.

Meanwhile, although not shown in the Drawings, a heater(not shown) may be installed within the central frame 420 in order to prevent polymer, particle, etc. from being deposited.

The heater is a component for preventing polymer, particle, etc. from being deposited on the surface by heating the adjacent dielectric window 100, etc.

What is claimed is:

1. A dielectric window supporting structure of an inductively coupled plasma (ICP) processing apparatus that comprises
a main container 10 that houses a substrate to be processed S to perform plasma processing,
a substrate mounting unit 20 on which the substrate to be processed S is mounted in the main container 10,
an exhaust system 30 that discharges gas from inside of the main container 10,
a dielectric window 100 that form an upper window of the main container 10, and
one or more RF antennas 40 which are installed to correspond to the dielectric windows 100 outside the main container 10 and to which RF power is applied to form induced electric field in the main container 10,
wherein the dielectric window 100 is formed as one body from one or more dielectric members, and bonded with a ceramic reinforcing member 120 to at least one surface of the upper surface and the lower surface of the dielectric window 100,
comprising a dielectric window supporting unit 500 supporting at least one of the dielectric window 100 and the ceramic reinforcing member 120 by penetrating at least one of the dielectric window 100 and the ceramic reinforcing member 120 and being connected with a supporting member 12 installed above the main container 10.

2. The dielectric window supporting structure of an inductively coupled plasma (ICP) processing apparatus of claim 1, wherein the dielectric window supporting unit 500 comprises
an expansion supporting portion 510 expanding in a horizontal direction for supporting at least one of the dielectric window 100 and the ceramic reinforcing member 120,
a supporting rod 520 for supporting at least one of the dielectric window 100 and the ceramic reinforcing member 120, the supporting rod 520 being connected with the expansion supporting portion 510 at one end thereof and with the supporting member 12 at the other end thereof.

3. The dielectric window supporting structure of an inductively coupled plasma (ICP) processing apparatus of claim 1, wherein the dielectric window 100 is integrated by bonding a plurality of divided dielectric members 110 with each other.

4. The dielectric window supporting structure of an inductively coupled plasma (ICP) processing apparatus of claim 2, wherein the plurality of divided dielectric members 110 are formed with stepped structure at the contacting surface with an adjacent dielectric member 110 so that a part of the dielectric member 110 interposes with each other when viewed in an upper and lower direction.

5. The dielectric window supporting structure of an inductively coupled plasma (ICP) processing apparatus of claim 3, wherein the divided plurality of the dielectric members 110 are bonded with each other by ceramic bonding.

6. The dielectric window supporting structure of an inductively coupled plasma (ICP) processing apparatus of claim 1, wherein the ceramic reinforcing member 120 is bonded and integrated with a plurality of horizontally divided ceramic reinforcing members.

7. The dielectric window supporting structure of an inductively coupled plasma (ICP) processing apparatus of claim 6, wherein the plurality of the divided ceramic reinforcing members are formed with stepped structure at the contacting surface with an adjacent ceramic reinforcing member so that a part of the ceramic reinforcing member interposes with each other when viewed in an upper and lower direction.
